(19) United States
(12) Patent Application Publication
(10) Pub. No.: US 2007/0262377 A1
(43) Pub. Date: Nov. 15, 2007

(54) Transistor Structure and Method of Manufacturing Thereof

(76) Inventor: Gil Asa, Zichron (IL)

Correspondence Address: NATH & ASSOCIATES, 112 South West Street, Alexandria, VA, 22314, US

(21) Appl. No.: 11/667,379

(22) PCT Filed: Nov. 10, 2005
(86) PCT No.: PCT/IL05/01178

§ 371 Date: May 9, 2007

Related U.S. Application Data
(60) Provisional application No. 60/626,472, filed on Nov. 10, 2004.

(51) Int. Cl. H01L 29/78; H01L 21/336

(52) U.S. Cl. 257/345; 438/289; 257/E29.255; 257/E21.409

(57) ABSTRACT

Method of manufacturing and a transistor structure thereof comprising: a pair of spaced apart regions forming a source region and a drain region and defining at least part of a channel region there between, the source region and the drain region comprising a semiconductor heavily doped with n-type impurity element and said channel region comprising a semiconductor lightly doped with n-type impurity element; and a pair of gates each being insulated from the channel region by a respective gate insulating layer and being disposed substantially symmetrically along the channel region on opposite sides of thereof; whereby in use independent voltages may be applied to said gates so as to modify conductivity of the channel.

### FIELD OF THE INVENTION

This invention relates to integrated circuits and, in particular, to transistor structures, devices comprising transistor structures and methods of manufacture thereof.

### BACKGROUND OF THE INVENTION

During the last decades, there has been an intensive race to scale down very large scale integration (VLSI) technology while retaining high yield and reliability. However, the miniaturization based on conventional MOSFET technology is limited, primarily because of leakage current and threshold voltage instability increasing with the degree of transistors' miniaturization.

The problem has been recognized in the Prior Art and various systems have been developed to provide a solution, for example:

U.S. Pat. No. 6,506,638 (Yu) discloses a method of manufacturing a vertical transistor utilizing a deposited amorphous silicon layer to form a source region. The vertical gate transistor includes a double gate structure for providing increased drive current. A wafer bonding technique can be utilized to form the substrate.

U.S. Pat. No. 6,534,822 (Xiang et al.) discloses a field effect transistor (FET) formed on “silicon on insulator” (SOI) substrate in the thin silicon layer above the insulating buried oxide layer. The channel region is lightly doped with an impurity to increase free carrier conductivity. The source region and the drain region are heavily doped with the impurity. A gate and a back gate are positioned along the side of the channel region and extending from the source region and each is fabricated of a metal with an energy gap greater than silicon to form Schottky junctions with the channel region.

U.S. Pat. No. 6,777,293 (Koscielnial) discloses a double diffused MOS (DMOS) transistor structure that uses a trench trough suitable for high-density integration with mixed signal analog and digital circuit applications. The DMOS device can be added to any advanced CMOS process using shallow trench isolation by adding additional process steps for trench trough formation, a trench implant and a P-body implant. The trench trough and trench implant provide a novel method of forming a drain extension for a high-voltage DMOS device.

U.S. Pat. No. 6,815,772 (Takemura) discloses a field effect type device having a thin film-like active layer, a top side gate electrode on the active layer and a bottom side gate electrode connected to a static potential, the bottom side gate electrode being provided between the active layer and a substrate. The bottom side gate electrode may be electrically connected to only one of a source and a drain of the field effect type device.

U.S. Patent Application No. 2004/092,060 (Gambino et al.) discloses a process for fabricating a metal oxide semiconductor field effect transistor (MOSFET) having a double-gate and a double-channel wherein the gate region is self-aligned to the channel regions and the source/drain diffusion junctions. The invention also relates to the FIN MOSFET structure.

U.S. Patent Application No. 2004/150,071 (Kondo et al.) discloses a semi-conductor device with a fin-type transistor formed in a projecting semiconductor region. The projecting semiconductor region is formed on a major surface of a semiconductor substrate of a first conductivity type. A gate electrode of the fin-type transistor is formed on at least opposed side surfaces of the projecting semiconductor region, with a gate insulating film interposed. Source and drain regions are formed in the projecting semiconductor region such that the source and drain regions sandwich the gate electrode. A channel region of the first conductivity type is formed in the projecting semiconductor region between the source and drain regions.

U.S. Patent Application No. 2004/253,774 (Boyanov et al.) discloses an apparatus including a straining substrate, a device over the substrate including a channel, wherein the straining substrate strains the device in a direction substantially perpendicular to a direction of current flow in the channel.

### SUMMARY OF THE INVENTION

There is a need in the art for a new semiconductor device and method of fabricating thereof capable of facilitating high density of integrated circuits with no degradation of their yield and performance.

The invention, in some of its aspects, is aimed to provide a novel solution capable of facilitating high density of integrated circuits with, practically, no degradation of their yield and performance.

In accordance with certain aspects of the present invention, there is provided a transistor structure and methods of manufacturing thereof, the transistor structure comprising:
a pair of spaced apart regions forming a source region and a drain region and defining at least part of channel therebetween, the source region and the drain region comprising a semiconductor heavily doped with n-type impurity element and said channel region comprising a semiconductor lightly doped with n-type impurity element; and
a pair of gates each being insulated from the channel region by a respective gate insulating layer and being disposed substantially symmetrically along the channel region on opposite sides of thereof; whereby in use independent voltages may be applied to said gates so as to modify conductivity of the channel.

In accordance with further aspects of the invention, a concentration of n-type impurity element in the channel region is adapted to facilitate at least partially un-depleted channel region under regular operating bias conditions and full depletion of the channel region when a potential between the gates exceeds a threshold voltage. A distance between said two gates is adapted to facilitate at least partially un-depleted channel region under regular operating bias conditions and full depletion of the channel region when a potential between the gates exceeds a threshold voltage.

The transistor structure may be implemented as a bulk channel transistor or as semiconductor-on-insulator channel transistor.

In accordance with further aspects of the present invention, the channel region may comprise two low mobility regions adjacent to the respective gate insulating layers. The low mobility region may be facilitated, for example, by positive ions embedded within the gate insulator layers, by an additional p-type layer disposed between the gate insulating layer and the channel region, etc.

In accordance with further aspects of the present invention, the channel may comprise substantially symmetrical inlets disposed in the vicinity of the gate insulating layers in respect to the source and drain, while a maximal depth Dₘₐₓ of each inlet is defined by the following equation:

$${D}_{max} = \sqrt{\frac{2 {ɛ}_{0} {ɛ}_{s} {ϕ}_{f}}{qN}} ,$$

where φ_{f} is a reference Fermi level defining as

$${ϕ}_{f} = \frac{kT}{q} ln ( \frac{N}{{n}_{i}} ) ,$$

N is the free electrons concentrations in the channel N-type region, ε₀ is the free space dielectric constant, εₛ is the semiconductor dielectric constant, q is the electron charge, nᵢ is the intrinsic carriers concentration T is the temperature and k is Boltzman constant. In certain embodiments of the present invention the inlets may be substantially symmetrical only in a direction normal to the substrate.

In accordance with certain aspects of the present invention, there is provided a transistor comprising the above transistor structure and being adapted to be “on” when the channel region is in a fully or partially un-depleted state and to be “off” when the channel region is in a substantially fully depleted state.

The transistor structure in accordance with the present invention may be used for variety of electronic devices, for example, a buffer circuit, an inverter circuit, a memory cell circuit, an amplifier and inverted amplifier circuit, etc.

In accordance with other aspects of the present invention there is provided a method of manufacturing a transistor structure comprising a pair of spaced apart regions forming a source region and a drain region and defining a channel therebetween, and a pair of gates each being insulated from the channel region by a respective gate insulating layer and being disposed substantially symmetrically along the channel region on opposite sides of thereof; the method comprising the following operations all carried out successively in the stated order:
a) forming a layer structure atop an oxidized semiconductor substrate, wherein said structure consecutively comprising a first n-type heavily doped semiconductor layer; a first insulator layer, an n-type slightly doped semiconductor layer, a second insulator layer and a second n-type heavily doped semiconductor layer;
b) forming the channel region, the gates and the insulating layers of the transistor structure;
c) forming two insulator regions disposed atop the oxidized substrate on opposite sides of the channel region and at least partly overlapping said channel region in a direction normal to the substrate;
d) forming an n-type heavily doped semiconductor layer around and above the structure resulting from c);
e) forming the source region and the drain regions; and
f) forming contacts to the gates, the source and the drain.

In accordance with other aspects of the present invention there is provided a method of manufacturing a transistor structure with an active region comprising a pair of spaced apart regions forming a source region and a drain region and defining at least part of a channel region therebetween, and a top gate and a back gate each being insulated from the channel region by a respective gate insulating layer and being disposed substantially symmetrically along opposite sides of the channel region, and a back tail to the back gate disposed aside the active region; the method comprising the following operations all carried out successively in the stated order:
a) forming a layer structure atop an oxidized semiconductor substrate, wherein said structure consecutively comprises a first n-type heavily doped semiconductor layer; a first insulator layer, an n-type slightly doped semiconductor layer, a second insulator layer and a second n-type heavily doped semiconductor layer;
b) sizing the layered structure in accordance with a desired size and position of the active region and the back tail;
c) forming the channel region, the back gate insulating layer, the back gate and the back tail thereof;
d) forming the top gate, the top gate insulating layer, the source region and the drain region such that the source region and the drain region at least partly overlap with the channel region in a direction parallel to the substrate.
e) forming inlets to the channel region, said inlets being disposed in a vicinity of the gate insulating layers and being substantially symmetrical with respect to the source and drain in a direction normal to the substrate.

### BRIEF DESCRIPTION OF THE DRAWINGS

In order to understand the invention and to see how it may be carried out in practice, some embodiments will now be described, by way of non-limiting example only, with reference to the accompanying drawings, in which:

FIGS. 1a-1b are generalized schematic views of several variants of a transistor structure in accordance with certain embodiments of the present invention.

FIG. 2a-2b shows generalized schematic views of certain alternative embodiments of a transistor structure in accordance with the present invention.

FIGS. 3a-3c show generalized cross-sectional views of the transistor structure in different depletion states.

FIG. 4 is a generalized I-V_{GB} curve of the transistor structure in accordance with certain embodiments of the present invention.

FIGS. 5a and 5b show generalized operations of the manufacturing process in accordance with certain embodiments of the present invention.

FIG. 6 shows generalized operations of the manufacturing process in accordance with certain alternative embodiments of the present invention.

FIG. 7 shows generalized operations of the manufacturing process in accordance with certain alternative embodiments of the present invention.

FIGS. 8a-8g are generalized circuit diagrams of several typical circuits constituted by combining transistors structures in accordance with certain embodiments of the present invention.

### DETAILED DESCRIPTION OF EXEMPLARY EMBODIMENTS

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention. In the drawings and descriptions, identical reference numerals indicate those components that are common to different embodiments or configurations.

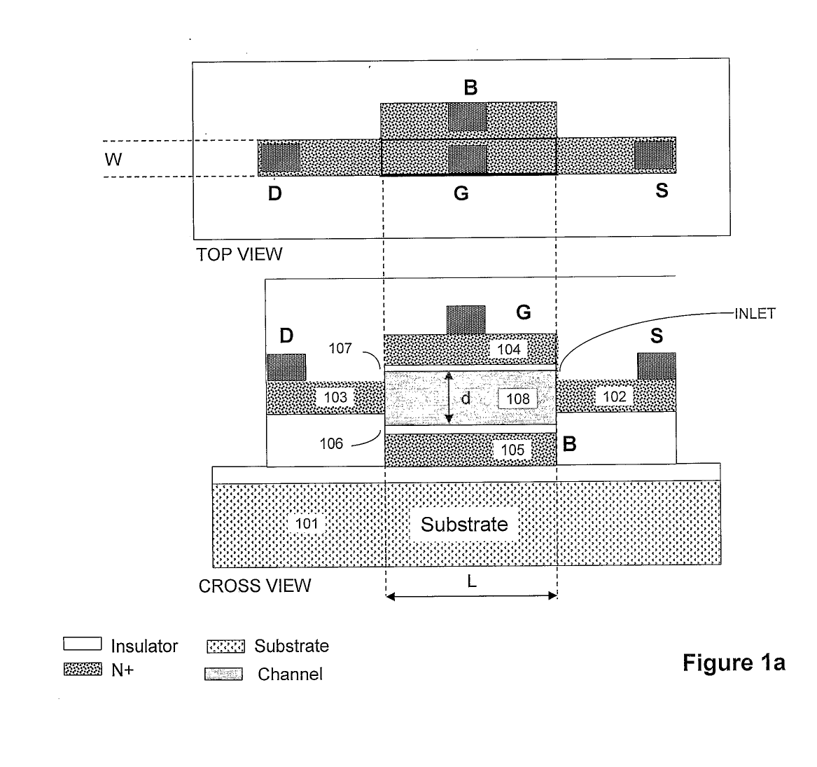

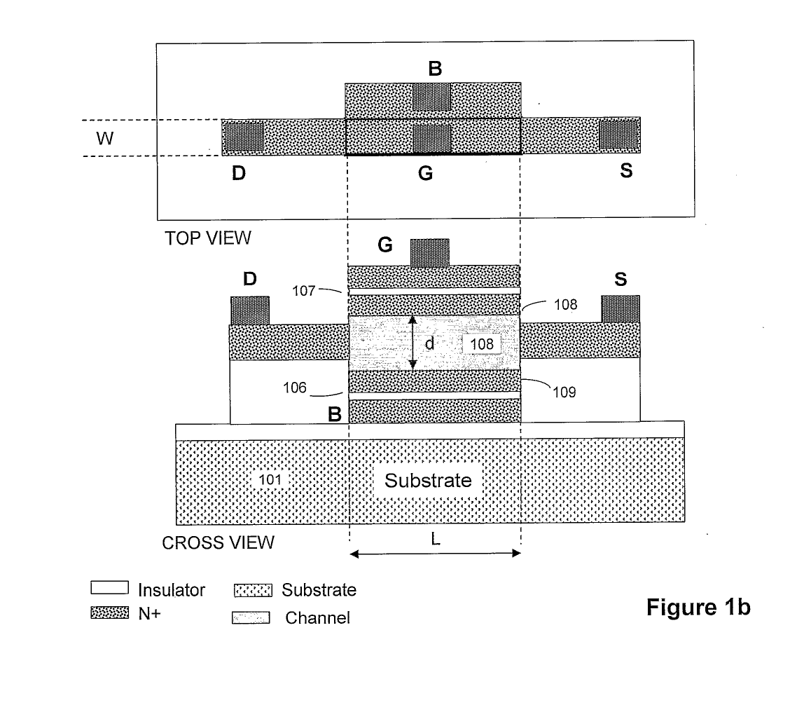

Bearing this in mind, attention is drawn to FIG. 1a illustrating cross-sectional and top views of a transistor structure in accordance with certain embodiments of the present invention. The illustrated transistor structure is formed within semiconductor (e.g. n-type or p-type Si, GaAs, etc.) on insulator (SOI) substrate 101. The structure contains heavy doped n⁺-type source region 102 and heavy doped n⁺-type drain region 103 manufactured using commonly known processes. A slightly doped n-type channel region 108 is located between the source 102 and the drain 103. The device further contains two heavily doped n⁺-type gates. The gates are substantially symmetrically disposed along the channel region on opposite sides of thereof, one at the top (top gate 104) and one at the bottom (back gate 105). The gates are separated from the substrate by corresponding gate insulating layers (e.g. SiO₂, SiN₄, etc.) 106 and 107. The gates have separate voltage and may be separately managed in order to control conductivity of the channel. In certain embodiments of the invention the back gate may have an outer space (back tail) facilitating convenient connection with the back gate contact.

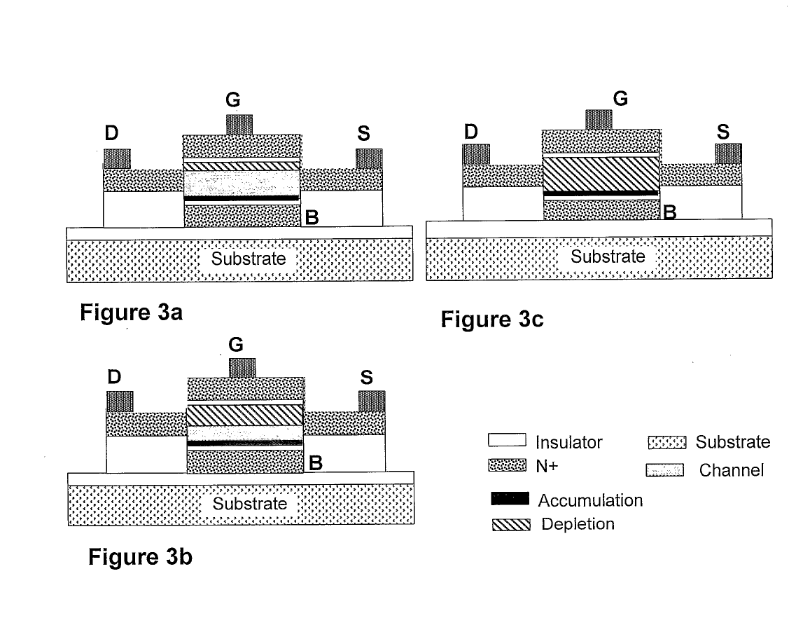

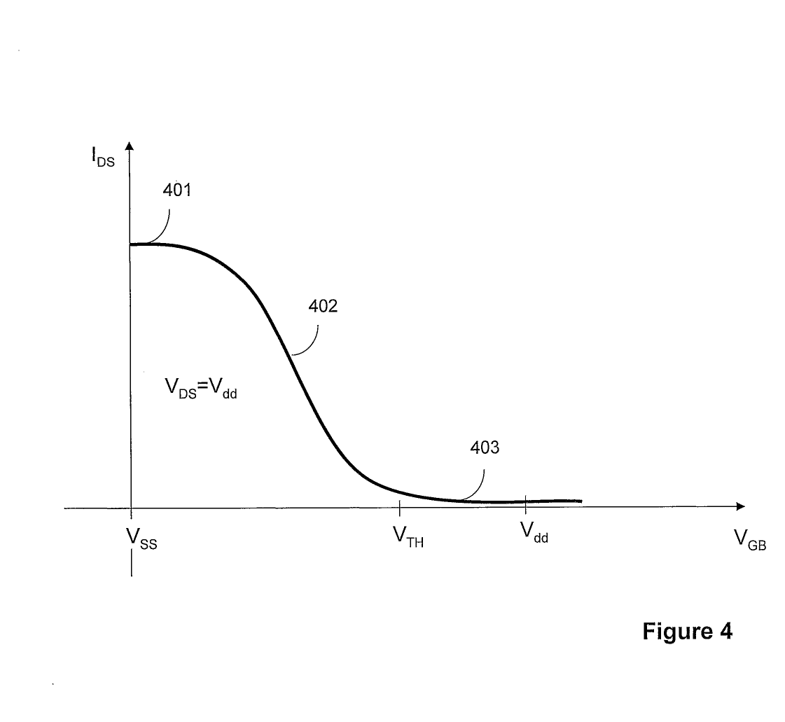

Typically, impurity concentration in the n⁺-type regions is high enough to facilitate an effective interface with metal contacts. Impurity concentration in the n-type channel region is low enough to facilitate channel region depletion under regular operating bias conditions, as will be further detailed with reference to FIGS. 3 and 4. Typically, the ratio of impurity concentrations in the n⁺-type region and the n-type region is 10²-10³.

As will be further detailed with reference to FIG. 3, when a voltage V_{G} applied to the top gate 104 is equal to a voltage V_{B} applied to the back gate 105, the entire channel stays neutral and electrons can flow freely between the source and the drain through the channel. This represents the “on” state. On the other hand, when V_{G}<V_{B}, the top gate 104 pushes electrons and forms a positive depleted layer, while the back gate 105 draws electrons and forms a negative accumulated layer (the total charge is always zero). As a bias voltage V_{GB} between the gates increases, the depletion layer becomes thicker, thus blocking the channel between the drain and the source. This represents the “off” state. The minimal voltage which cuts off the device will be denoted hereinafter as “the threshold voltage” (V_{TH}). Thus, as opposed to traditional CMOS transistors, in the transistor in accordance with the present invention a fully depleted state is considered as “off” and a fully or partially un-depleted state is considered as “on”.

The planar dimensions of the structure elements may be equal or less than the respective dimensions in commonly known CMOS transistors. Unlike typical CMOS transistors, the thickness of the structural elements is not strictly limited; for example, in certain embodiments of the present invention the thickness of the gate insulating layer may be 3-5 times more than is required for CMOS transistors.

The following parameters illustrate, by way of non-limiting example, the elements of the above transistor structure:
N-type carrier concentrations: 1016 cm-3
N+region carrier concentration: 1019 cm-3
Gate Insulator thickness: 7 nm
Channel thickness (d): 150 nm
Channel length (L): 150 nm
Channel width (W): 1-5 L

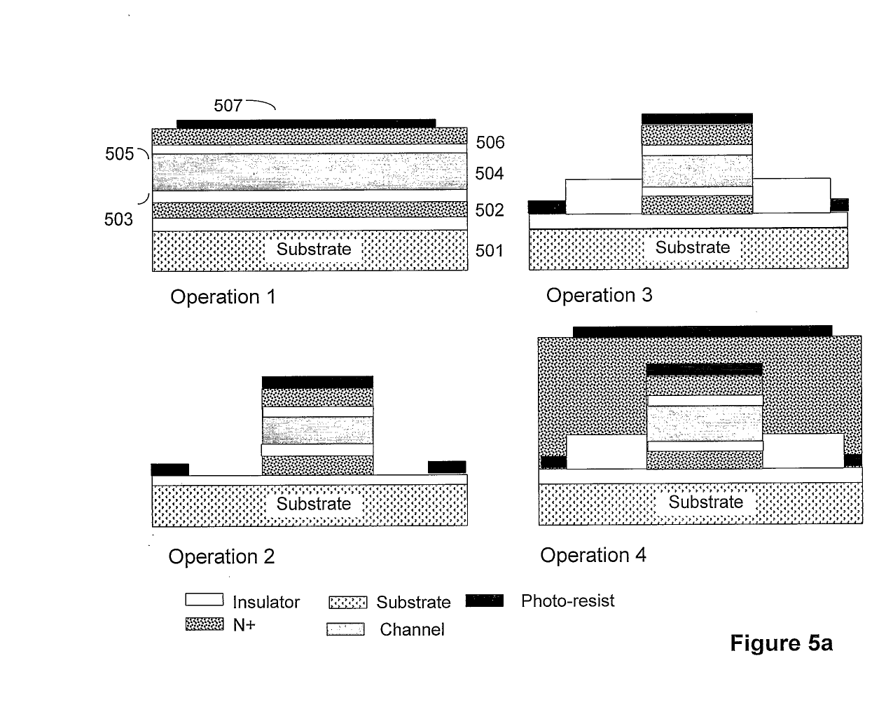

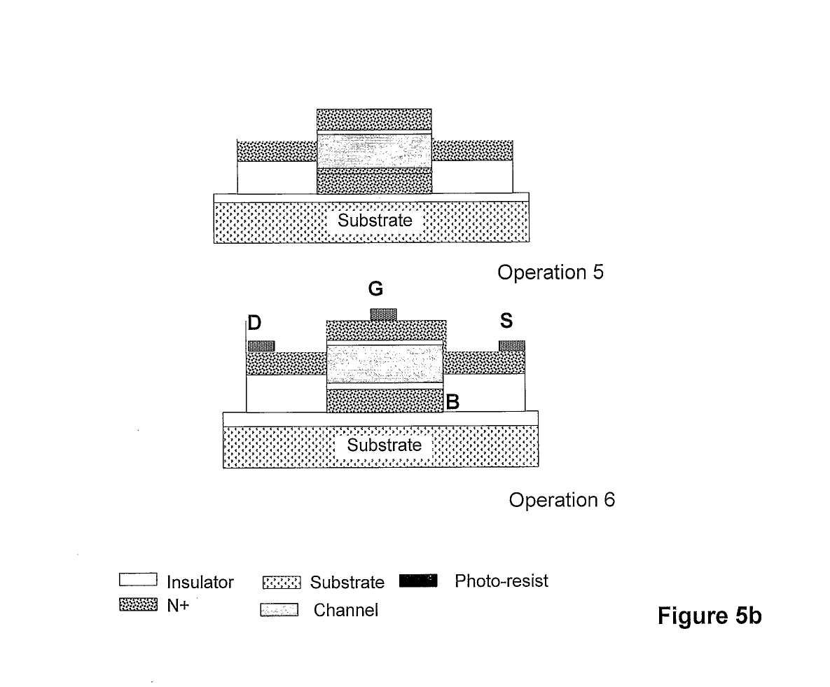

In certain embodiments of the invention, the channel may have substantially symmetrical inlets in respect to the source and drain disposed in the vicinity of the gate insulating layers. These inlets ensure a perfect cut-off of the channel by the depletion layer. The maximal size of the inlets is further detailed with reference to FIG. 5a.

FIG. 1b illustrates the above transistor structure with enhanced capabilities. Two additional heavily doped n⁺-type layers 108 and 109 are disposed on both sides of the channel between the channel and the respective gate insulator layers. When the transistor is in the “on” state, these additional layers enhance the conductance between the source and the drain. When the transistor is in the “off” state, the channel is fully depleted and the carriers cannot reach the enhancement layers.

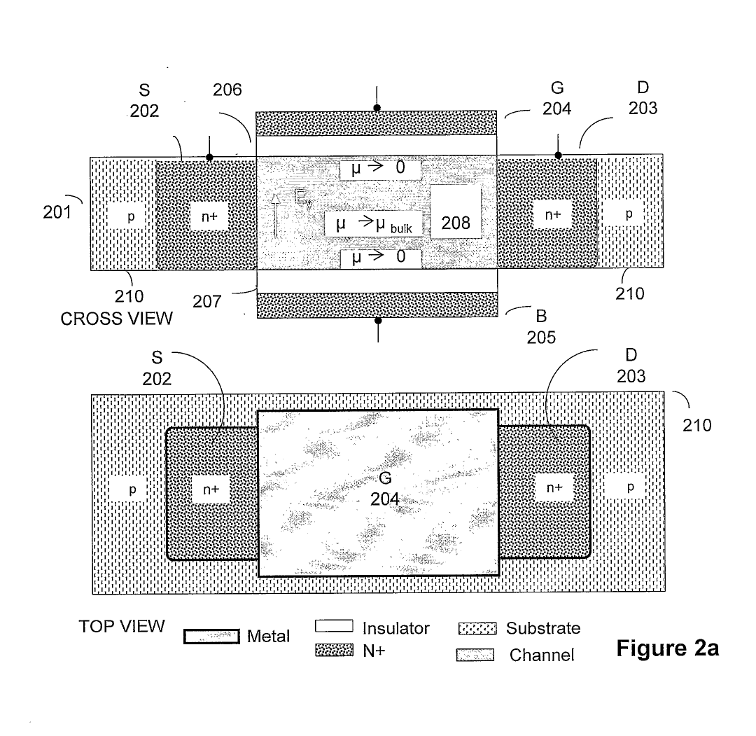

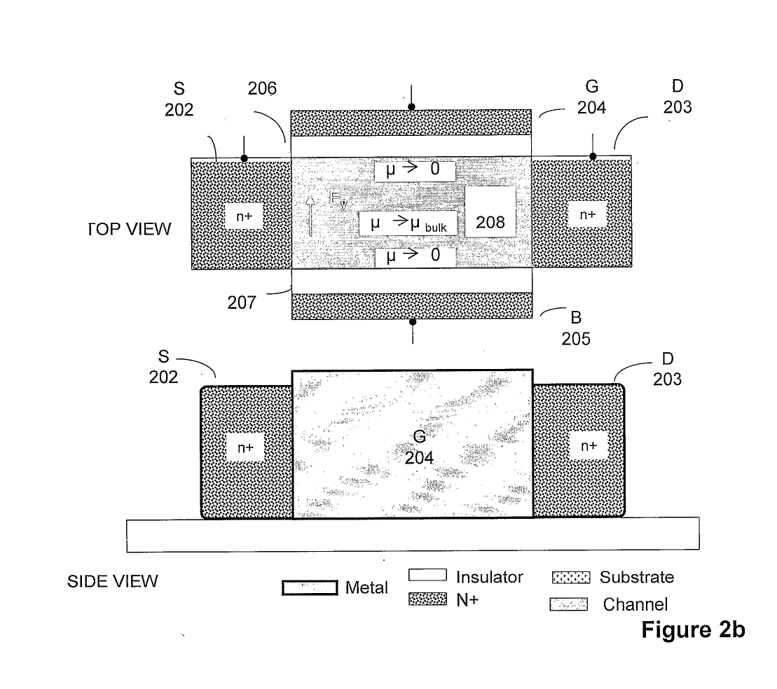

FIG. 2a illustrates cross-sectional and top views of certain alternative embodiments of a transistor structure in accordance with the present invention. The transistor structure is formed in a bulk substrate of a semiconductor material 201 (e.g. n-type or p-type Si, GaAs, etc.) in a manner similar to the structure described with reference to FIG. 1a. In the illustrated embodiment, the n⁺-type source region 202 and the n⁺-type drain region 203 extend from a top to a bottom of the substrate 201. The channel region 208 connects the source and the drain regions and is sandwiched between two (top and bottom) gate insulator layers 206 and 207. The device further contains two separately managed gates, one at the top of the insulator layer 206 (gate 204) and one at the bottom of the insulator layer 207 (back gate 205) of the substrate. A p-type region 209 surrounds the transistor structure to provide electrical insulation from other elements of an integrated circuit.

To ensure low leakage at the “off” state of the transistor structure in certain embodiments of the invention, some special measures may be provided in order to prevent accumulation of electrons under the gates and, accordingly, enable low electron mobility near the interfaces “gate insulator/substrate.” By such means, in certain embodiments of the invention the electron mobility in the interface layer may be less than 10⁻³ of the electron mobility in the substrate (bulk mobility). The low mobility in this region may be achieved in different ways. For example, embedding of positive ions (e.g. Na+ or K+) within the insulator layers may provide a positive charge which, in combination with a strong electric field between the gates, can hold the electrons unmoved when the device is in the ‘OFF’ state. The effect of positive ions embedded in SiO₂ is described, for example, in E. H. Nicollian, J. R. Brews, “MOS Physics and Technology”, 2003, page 424 and chapter 11. Another solution is, for example, to form thin p-type layers under the insulator in the substrate near the interfaces “gate insulator/substrate”. These solutions may also ensure low leakage at the “off” state of the SoI transistor structure detailed with reference to FIGS. 1a-1b.

FIG. 2b illustrates a planar variant of the embodiment of the transistor structure illustrated in FIG. 2a, wherein the source, the drain, the gates and the channel are disposed in one plane atop of oxidized substrate (i.e. left and right gates instead of top and bottom gates).

It should be noted that although further figures are described with reference to the transistor structure illustrated in FIG. 1a, the invention is not bound by this specific embodiment. Those versed in the art will readily appreciate that the invention is, likewise, applicable to other embodiments, such as those described with reference to FIG. 1b and FIGS. 2a-2c.

Referring to FIGS. 3a-3c, there are illustrated generalized cross-sectional views of the transistor structure in different depletion states. The depletion states are illustrated in dependence on bias between the source and the drain while the potential between the gates V_{GB} is less than the threshold voltage V_{TH}. An electron flow in the channel is ruled by two independent bias sources: V_{GB} and V_{DS}. When V_{GB}=0, the channel is pseudo-neutral since each electron entering from the source is followed by an electron leaving from the drain. The device in this case is fully conductive. When 0<V_{GB}<V_{TH}, electrons are pushed from the negative gate towards the positive gate. Consequently the channel starts to get blocked by a depletion layer, which does not conduct since it is poor in electrons. The device in this case (FIG. 3b) is partially conductive. It should be emphasized, that the transistors shown in both FIGS. 3a and 3b act linearly as a resistor but R_{B}>R_{A}, where R_{A} and R_{B} denote the respective resistance. Consequently, unlike other transistors, the transistor structure in accordance with certain aspects of the present invention will not come to saturation. When V_{GB}≧V_{TH}, the depletion layer covers the source (or the drain) electron entrance and blocks the current. The device in this case (FIG. 3c) is cut off.

The voltage between the gates is the sum of the voltage on the insulator plus the voltage on the channel N-type region:

$${V}_{GB} = {E}_{I} \cdot 2 {t}_{I} + \frac{{E}_{S} {Y}_{d}}{2} = \frac{{qNY}_{d}}{{ɛ}_{0} {ɛ}_{I}} \cdot 2 {t}_{I} + \frac{{qNY}_{d}}{{ɛ}_{0} {ɛ}_{S}} \cdot \frac{{Y}_{d}}{2}$$

wherein:

E_{I} is the insulator electric field,

t_{I} is the insulator thickness,

E_{S} is the maximum semiconductor electric field,

Y_{d} is the depletion depth,

q is the electron charge,

N is the free electrons concentrations in the channel N-type region,

ε₀ is the free space dielectric constant,

ε_{I} is the insulator dielectric constant, and

ε_{S} is the semiconductor dielectric constant.

In order to calculate the maximal value of the depth of depletion Y_{d} it is necessary to solve the above equation when V_{GB}=(kT/q)*2ln(N/nᵢ)=2φ_{f},

where:

φ_{f} is a reference Fermi level and

nᵢ is the intrinsic carriers concentration,

‘k’ is Boltzmann constant, and

T is the temperature.

For example, calculated for typical for MOS devices values (e.g. V_{GB}=1V, d=1μ, N=10¹⁶/cm³, t_{I}=70 Å.), the maximal depth of the channel region is about 150 nm.

Referring to FIG. 4, there is illustrated a generalized I-V_{GB} curve of the transistor structure in accordance with certain embodiments of the present invention. When V_{GB} is small, the device is “on” (401). The device becomes partially conductive (402) as V_{GB} increases, and enters the “off” state (403) when V_{GB}>V_{TH}.

Table 1 summarizes the behavior of the transistor structure in accordance with certain embodiments of the present invention.

TABLE 1

| | V_{g} = V_{dd}; | V_{g} = 0; | V_{g} = V_{dd}; | V_{g} = 0; |
|---|---|---|---|---|
| | V_{b} = 0 | V_{b} = 0 | V_{b} = V_{dd} | V_{b} = V_{dd} |
| Transistor's | Off | On | On | Off |
| state | | | | |
| Channel state | Depletion | Quasi-neutral | Quasi-neutral | Depletion |

FIGS. 5a and 5b illustrate generalized operations of manufacturing process in accordance with certain embodiments of the present invention, in particular, illustrated in FIG. 1a.

Operation 1 forms layers of the transistor structures for the entire chip. An n-type layer 502 of heavily doped material, a future back gate(s), is deposited on an oxidized semiconductor wafer 501. Further creation of thin gate insulator layer 503 is followed by depositing a layer 504 of slightly doped n-type silicon, a future transistor channel(s). The term “silicon” used in this patent specification should be expansively construed to cover any material containing silicon, including, but not limited to Si, SiGeC, SiC, polysilicon, epitaxial silicon, amorphous silicon and multilayer thereof. It follows by creating an upper gate thin insulator layer 505, depositing a layer 506 of n-type heavily doped material for a future top gate and forming a first photo-resist mask 507 corresponding to areas of future channels and gates. The exemplary thickness of the layers is illustrated, by way of non-limiting example, in Table 2.

TABLE 2

| | Layer | | | | |
|---|---|---|---|---|---|
| | 502 | 503 | 504 | 505 | 506 |
| Thickness (nm) | 90 | 7 | 150 | 7 | 90 |

Operation 2 facilitates formation of the gates and the channel and comprises a multistage etching of all layers. The etching stops upon reaching the back gate layer 502, the area designated for back-tail is masked by additional photo-resist, and the etching continues until all un-masked parts are removed.

Operation 3 comprises creating insulator shoulders 106 and 107 on two sides of the structure resulting from the Operation 2. The created insulator may be an oxide, a nitride, an oxynitride or any combination thereof including multilayers. These two ‘shoulders’ will carry the future drain and source (caution must be taken to prevent oxidation of the channel). The photo-resist from the previous operations acts here to block oxidation of the top gate. The thickness of the insulator shoulders facilitates the desired size of inlet. The size of the inlet may be between zero and maximal size Dₘₐₓ defined by the following equation:

$${D}_{max} = \sqrt{\frac{2 {ɛ}_{0} {ɛ}_{s} {ϕ}_{f}}{qN}} , where {ϕ}_{f} = \frac{kT}{q} ln ( \frac{N}{{n}_{i}} )$$

Operation 4 comprises_creating a heavy doped n+ silicon layer around and above the structure resulting from the Operation 3 and covering the transistor area with a photo-resist mask.

Operation 5 comprises removing (e.g. by etching, Ion Beam Milling, etc.) n+ material around the transistor structure, removing top photo-resist, and forming the drain and the source regions. The etching (milling, etc.) stops upon reaching the level of a desired top of the source and drain regions, the area designated for the source and the drain is masked by additional photo-resist, and the etching (milling, etc.) continues until all un-masked parts are removed. After that, photo-resist is removed from the tops of the top gate, back-tail of the back gate, the drain and the source.

Operation 6 comprises deposition of metal contacts to the gates, the source and the drain, metal interconnection between the transistor structures within an electronic device and opening space between the transistor structures.

The illustrated method facilitates self alignment between the top and the back gates. Moreover, since the illustrated method comprises growing of an electronic device on a planar oxide and can be also ended in planar oxide, additional transistor floor can be constructed on top of the first one by repeating the above Operations 1-6.

It is to be understood that the invention is capable of other manufacturing methods and that the illustrated process of manufacture may be carried out in various ways known in the art.

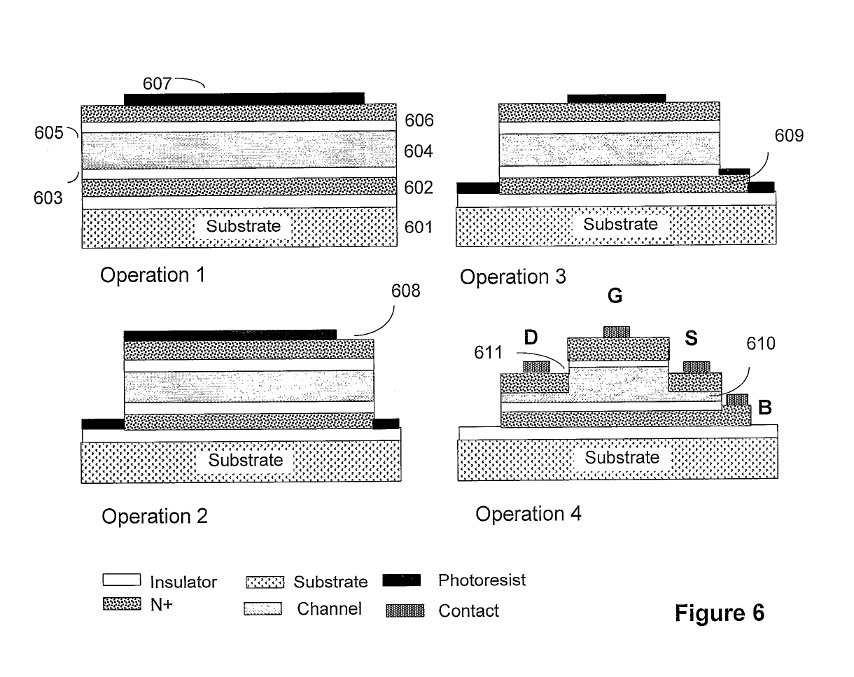

FIG. 6 illustrates generalized operations of manufacturing process in accordance with certain alternative embodiments of the present invention, in particular, for SOI transistor structure.

Operation 1 forms layers of the transistor structures as was detailed with reference to Operation 1 in FIG. 5a forms layers of the transistor structures for the entire chip. An n-type layer 602 of heavily doped material, a future back gate(s), is deposited on an oxidized semiconductor wafer 601. Further creation of thin gate insulator layer 603 is followed by depositing a layer 604 of slightly doped n-type silicon, a future transistor channel(s). It follows by creating an upper gate thin insulator layer 605, depositing a layer 606 of n-type heavily doped material for a future top gate and forming a first photo-resist mask 607 corresponding to the transistor structure (including source and drain).

Operation 2 comprises removing all materials not covered by the first photo-resist mask 607 and forming a second photo-resist mask covering the entire chip except an area 608 designated for back-tail of the back gate.

Operation 3 comprises removing all materials not covered by the second photo-resist mask, creating the back-tail 609 and forming a third photo-resist mask covering all the surfaces except an area designated for the source and for the drain.

Operation 4 comprises removing materials not-covered by the third mask and self-aligned forming the source and the drain. The etching (milling, etc.) stops upon reaching the level of a desired inlet 610 to be created in vicinity of the back gate, and the drain and the source are formed by ion implantation (or other method) with a size enabling a desired inlet 610 in vicinity of the top gate. After that, the photo-resist is removed and metal contacts are deposited to the drain, the source and the gates. In the resulting transistor structure the inlet area of the channel also spreads under the source and the drain and the inlets are substantially symmetrical only in a direction normal to the substrate. The maximal size of the inlets is defined in a manner described with reference to FIG. 5a.

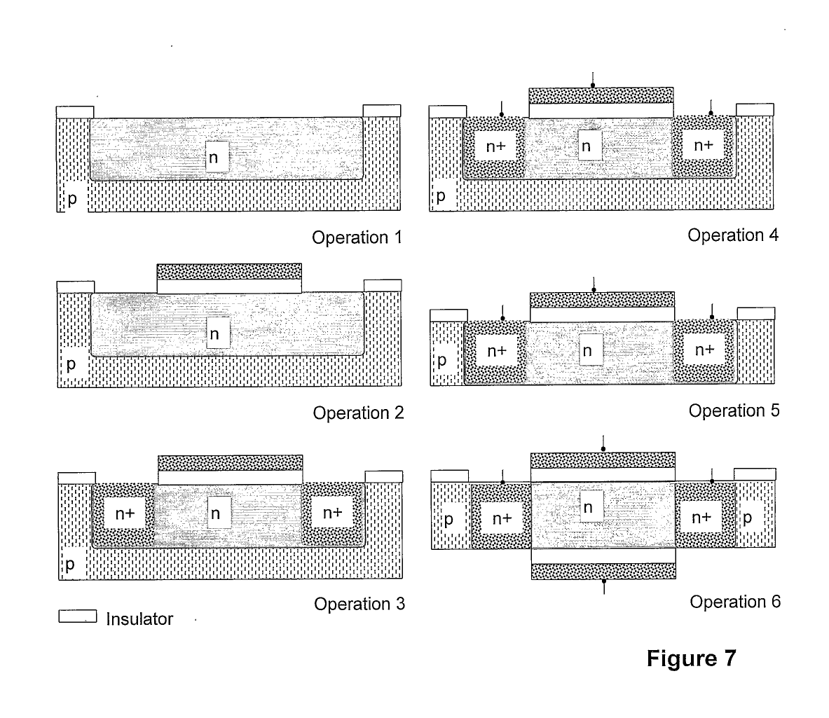

FIG. 7 illustrates generalized operations of the manufacturing process in accordance with certain other embodiments of the present invention, in particular, a bulk channel transistor as illustrated in FIG. 2.

Operation 1 includes a process of creation (e.g. implantation) of n-type channel region into p-type silicon substrate (e.g. via openings in the first field insulator). Operation 2 includes the formation of the top gate insulator and the top gate. Operation 3 includes the implantation of the n+ regions (future source and drain regions), which are self aligned to the prior operations, as in well known MOS fabrication processes. Operation 4 includes formation (e.g. by deposition) of insulator and metal layers for, e.g., circuit interconnection. The last insulating layer must be thick enough to facilitate mechanical base for the next operations. Operation 5 includes a precise polishing of the back side of the wafer in order to make the height of the substrate substantially equal to a predefined depth of the channel region. Operation 6 includes formation of the back side gate, this process being self aligned to Operation 5. Operation 7 (not illustrated in FIG. 7) includes deposition of insulators and metal layers on the backside of the wafer, thus forming the backside circuit interconnection.

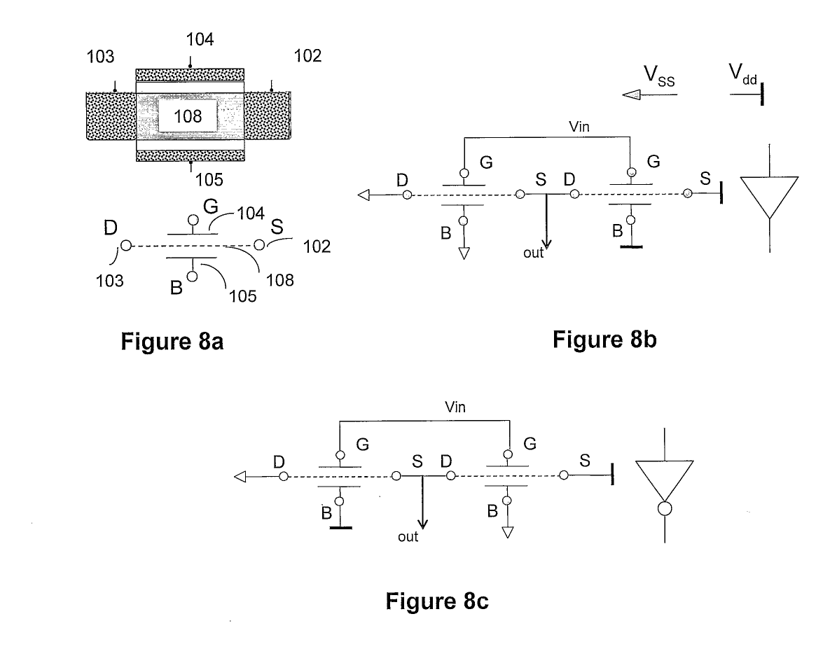

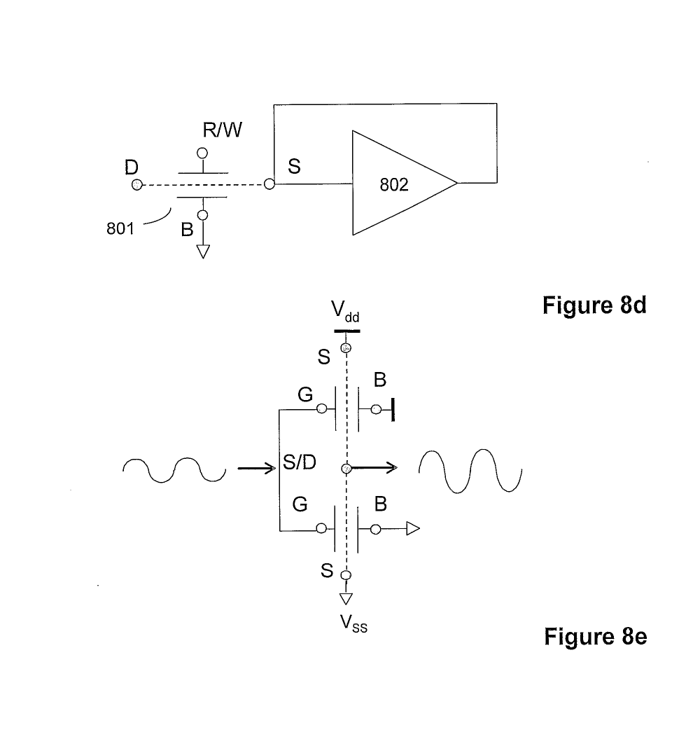

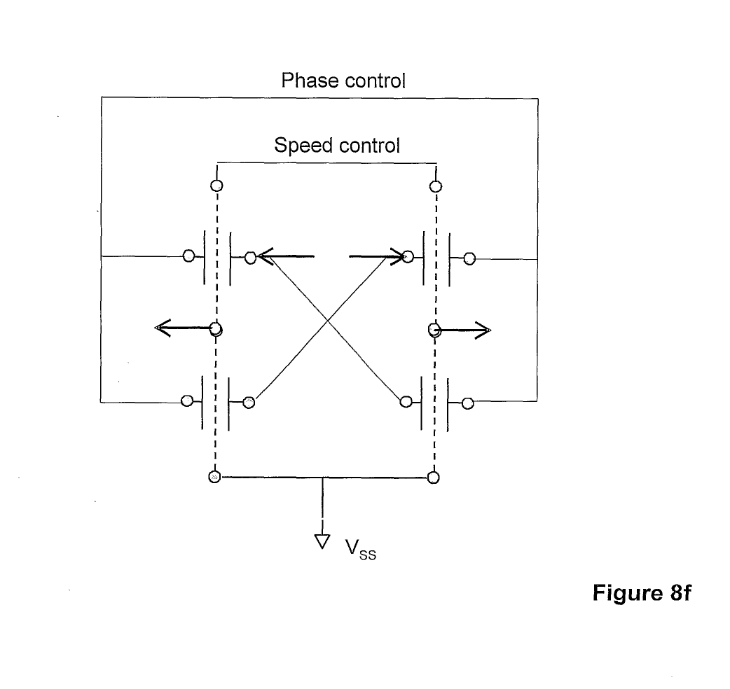

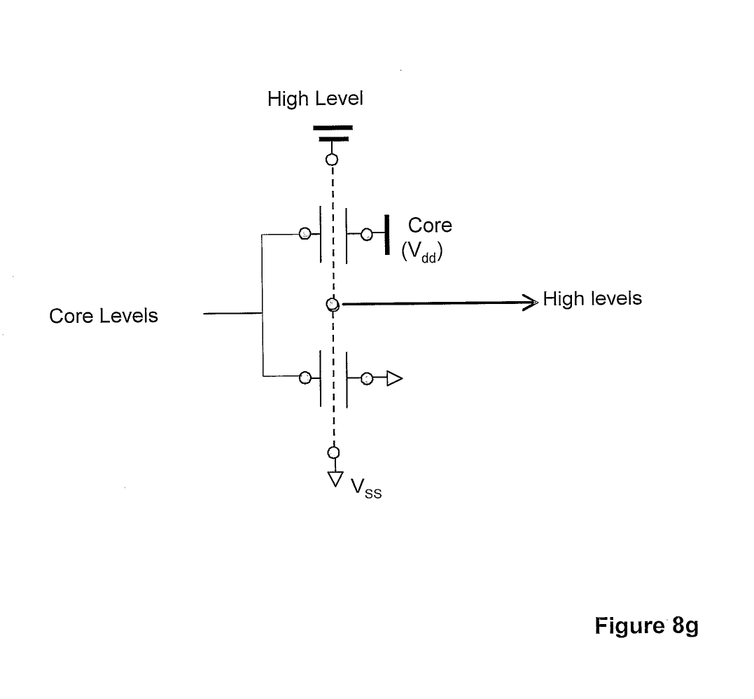

Referring now to FIGS. 8a-8g, there are illustrated generalized circuit diagrams of several typical circuits constituted by combining transistors structures in accordance with certain embodiments of the present invention. FIG. 8a illustrates the schematic elements of the transistor structure further used in the illustrating circuit diagrams. The drain 103 will be further denoted as D, the source 102 will be further denoted as S, the gates 104 and 105 will be further denoted as G and B and the n-channel region 108 will be illustrated by the dashed line connecting the source and the drain.

FIGS. 8b and 8c schematically illustrate buffer and inverter circuits respectively. Note that, unlike CMOS circuits, two transistor structures of the present invention are enough to constitute these circuits. Thus, even if the transistor structure of the current invention has the same size as a conventional CMOS transistor, the area required for the resulting inverter circuit will be at least halved and the area required for the resulting buffer will be at least four times smaller than the same functionality circuits constituted from the conventional CMOS transistors. These two basic types (buffer and inverter) can be directly extended to a full set of logical functions. For example, the buffer can be extended to AND & OR circuit with just a minor delay, and the inverter can be extended to NAND & NOR circuits with the same benefit. Since there is no need for PMOS here, and there is no V_{TH} drop, these gates should be high fan out/ high fan in, low power and much faster than typical CMOS. The thick gate insulator assures low capacitance load between the gates.

Bearing this in mind, attention is drawn to FIG. 8b. When the input voltage Vᵢₙ=V_{dd}, the right transistor is ON (V_{GB}=0) and the left transistor is OFF (V_{GB}=V_{dd}). Consequently, the resistance of the right transistor becomes about 10⁵ times smaller than the resistance of the left transistor and the output will be pulled up to V_{dd}. Note that unlike the MOS transistor, when in=V_{dd} (or in=0), the transistors in FIG. 8b behave like ideal resistors because the channel resistance is independently controlled by V_{GB} and not V_{GS}. This feature is the key to the possibility to use only n-channel transistors in this embodiment. If the right transistor in FIG. 8b were n-MOS, then for Vᵢₙ=V_{dd} the output would be pulled up only to V_{dd}−V_{TH} as n-MOS threshold condition is V_{GS}=V_{TH}.

For the inverter illustrated in FIG. 8c, the output terminal n+ region is common to both transistors. When Vᵢₙ=V_{dd}, the left transistor is ON (V_{GB}=0) and the right transistor is OFF (V_{GB}=V_{dd}), accordingly, the output will be pulled down to V_{SS}. Alternatively, if in=0, the right transistor is ON (V_{GB}=0) and the left transistor is OFF (V_{GB}=−V_{dd}) and the output will be pulled up to V_{dd}.

It should be noted, that in certain embodiments of the present invention, a single transistor structure may operate as a transfer gate. Unlike CMOS transfer gate utilizing PMOS & NMOS, the transistor structure of the present invention may conduct like a linear voltage controlled resistor in both directions. Furthermore, a capacitance C_{GS} between gate and source and a capacitance C_{GD} between gate and drain shall be much smaller thus reducing the kick back phenomena to a minor level.

In accordance with certain aspects of the present invention, a memory cell illustrated in FIG. 8d may be implemented with only two transistors. The illustrated circuit comprises a read/write (R/W) transfer gate transistor 801 and a sustainer 802 (the buffer described with reference to FIG. 8b in a closed loop) When the transfer gate is switched ON the memory cell is exposed to read/write operations, and if the transfer gate is OFF, the cell holds its last data. The illustrated memory cell may be a key element for compact memories, flip flops and latching devices.

FIGS. 8e and 8f schematically illustrate, respectively, amplifiers in single end and differential mode in accordance with certain embodiments of the present invention. The amplifier illustrated in FIG. 8e comprises the buffer circuit illustrated in FIG. 8b and a signal operation circuit, which upon small signal sine wave at the input gives amplified sine at the output with the same phase. The amplifier shall be more linear than CMOS amplifier, as the I-V characteristic of the transistor structure in accordance with certain embodiments of the present invention is closer to that of a resistor.

The differential amplifier illustrated in FIG. 8f comprises only four transistors with cross-coupled gates, which force the outputs to be differential.

Referring to FIG. 8g, there is illustrated a generalized circuit diagram of a level shifter. The two-transistor buffer is connected to an analog level, which is higher than V_{dd} in order to form level shifting. The upper transistor can be cut off for V_{GB}=V_{dd}, no matter what the value of V_{DS} or V_{GS}. In accordance with certain embodiments of the present invention the level may be shifted with one buffer stage with no latching stage commonly used in conventional level shifters.

It should be noted that the exemplary circuits illustrated in FIGS. 8a-8g can be the building elements for most of the integrated circuits. However, the transistor structures implemented in accordance with the present invention may constitute other circuits also.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present invention.

Those skilled in the art will readily appreciate that various modifications and changes can be applied to the embodiments of the invention as hereinbefore described without departing from its scope, defined in and by the appended claims.

1-31. (canceled)

32. A transistor structure comprising:
a pair of spaced apart regions forming a source region and a drain region and defining at least part of a channel region there between, the source region and the drain region comprising a semiconductor heavily doped with n-type impurity element and said channel region comprising a semiconductor with n-type impurity element; and
a pair of gates each being insulated from the channel region by a respective gate insulating layer and being disposed substantially symmetrically along the channel region on opposite sides of thereof, said gates being adapted to control a current in the channel region by applying independent voltages;
characterized in that:
a ratio of impurity concentration in the heavily doped region to impurity concentration in the channel region is substantially in a range between 10² and 10³; and the channel region is provided with a pair of low mobility regions each adjacent to a respective one of the gate insulating layers;
whereby in use the current in the channel region is substantially cut off when a difference between the voltages applied to the gates exceeds a threshold value.

33. The transistor structure of claim 32 wherein said gates have substantially equal sizes.

34. The transistor structure of claim 32 wherein the channel region is at least partially un-depleted under regular operating bias conditions.

35. The transistor of claim 32, wherein the channel region fully depleted when a potential between the gates exceeds a threshold voltage.

36. The transistor structure of,claim 32, wherein a distance between the two gates is dimensioned to facilitate at least partially un-depleted channel region under regular operating bias conditions.

37. The transistor structure of claim 32, wherein a distance between the two gates is dimensioned to facilitate full depletion of the channel region when a potential between the gates exceeds a threshold voltage.

38. The transistor structure of claim 32 implemented as a bulk channel transistor.

39. The transistor structure of claim 32 implemented as semiconductor-on-insulator channel transistor.

40. The transistor structure of claim 32, wherein the low mobility region is facilitated by positive ions embedded within the gate insulator layers.

41. The transistor structure of claim 32, wherein the low mobility region is facilitated by an additional p-type layer disposed between the gate insulating layer and the channel region.

42. The transistor structure of claim 32, wherein the channel region comprises inlets disposed in the vicinity of the gate insulating layers and substantially symmetrical in respect to the source and drain in a direction normal to the substrate.

43. The transistor structure of claim 42, wherein a maximal depth Dₘₐₓ of each inlet is defined by
$${D}_{max} = \sqrt{\frac{2 {ɛ}_{0} {ɛ}_{s} {ϕ}_{f}}{qN}} ,$$
where φ_{f} is a reference Fermi level defined as
$${ϕ}_{f} = \frac{kT}{q} ln ( \frac{N}{{n}_{i}} ) ,$$
N is the concentration of free electrons in the channel N-type region, ε₀ is the free space dielectric constant, ε_{S} is the semiconductor dielectric constant, q is the electron charge, nᵢ is the intrinsic carriers concentration, T is the temperature, and k is Boltzmann constant.

44. The transistor structure of claim 42, wherein the source region and the drain region at least partly overlap with the channel region in a direction parallel to the substrate.

45. The transistor structure of claim 32 comprising two heavily doped n-type layers being disposed along the channel region on opposite sides thereof between the channel region and the respective insulating layer.

46. The transistor structure of claim 32, wherein the channel region is not inverted under regular operating bias conditions.

47. A transistor comprising the transistor structure in accordance with claim 32, said transistor being adapted to be “on” when the channel region is in a fully or partially un-depleted state and to be “off” when the channel region is in a substantially fully depleted state.

48. An electronic device comprising at least one transistor structure, said transistor structure comprising:
a pair of spaced apart regions forming a source region and a drain region and defining at least part of a channel region there between, said source region and the drain region comprising a semiconductor heavily doped with n-type impurity element and said channel region comprising a semiconductor with an n-type impurity element, and a pair of gates each being insulated from the channel region by a respective gate insulating layer and being disposed substantially symmetrically along the channel region on opposite sides thereof; said gates being,adapted to control a current in the channel region by applying independent voltages;
characterized in that:
a ratio of impurity concentration in the heavily doped region to impurity concentration in the channel region is substantially in a range between 10² and 10³; and
the channel region is provided with a pair of low mobility regions each adjacent to a respective one of the gate insulating layers;
whereby in use the current in the channel region is substantially cut off when a difference between the voltages applied to the gates exceeds a threshold value

49. A buffer circuit comprising the transistor structure in accordance with claim 32.

50. A buffer circuit comprising two identical transistor structures in accordance with claim 32.

51. An inverter circuit comprising the transistor structure in accordance with claim 32.

52. An inverter circuit comprising two identical transistor structures in accordance with claim 32.

53. A memory cell circuit comprising the transistor structure in accordance with in accordance with claim 32.

54. A memory cell circuit comprising three identical transistor structures in accordance with claim 32.

55. An amplifier circuit comprising the transistor structure in accordance with claim 32.

56. A differential amplifier circuit comprising the transistor structure in accordance with claim 32.

57. A differential amplifier circuit comprising four identical transistor structures in accordance with claim 32.

58. A method of manufacturing a transistor structure comprising a pair of spaced apart regions forming a source region and a drain region and defining a channel region there between, and a pair of gates each being insulated from the channel region by a respective gate insulating layer and being disposed substantially symmetrically along the channel region on opposite sides of thereof; the method comprising the following operations all carried out successively in the stated order:
a. forming a layer structure atop an oxidized semiconductor substrate, wherein said layer structure consecutively comprises a first n-type heavily doped semiconductor layer; a first insulator layer, an n-type slightly doped semiconductor layer, a second insulator layer and a second n-type heavily doped semiconductor layer;
b. forming the channel region, the gates and the insulating layers of the transistor structure;
c. forming two insulator regions disposed atop the oxidized substrate on opposite sides of the channel region and at least partly overlapping said channel region in a direction normal to the substrate;
d. forming an n-type heavily doped semiconductor layer around and above the structure resulting from c);
e. forming the source region and the drain regions; and
f. forming contacts to the gates, the source and the drain.

59. A method of manufacturing a transistor structure with an active region comprising a pair of spaced apart regions forming a source region and a drain region and defining at least part of a channel region there between, and a top gate and a back gate each being insulated from the channel region by a respective gate insulating layer and being disposed substantially symmetrically along opposite sides of the channel region, and a back tail to the back gate disposed aside the active region; the method comprising the following operations all carried out successively in the stated order:
a. forming a layer structure atop an oxidized semiconductor substrate, wherein said structure consecutively comprises a first n-type heavily doped semiconductor layer; a first insulator layer, an n-type slightly doped semiconductor layer, a second insulator layer and a second n-type heavily doped semiconductor layer;
b. sizing the layered structure in accordance with a desired size and position of the active region and the back tail;
c. forming the channel region, the back gate insulating layer, the back gate and the back tail thereof;
d. forming the top gate, the top gate insulating layer, the source region and the drain region such that the source region and the drain region at least partly overlap with the channel region in a direction parallel to the substrate;
e. forming inlets to the channel region, said inlets being disposed in a vicinity of the gate insulating layers and being substantially symmetrical with respect to the source and drain in a direction normal to the substrate; and
f. forming contacts to the gates, the source and the drain.

60. The method of claim 59, wherein a maximal depth Dₘₐₓ of each inlet is defined by:
$${D}_{max} = \sqrt{\frac{2 {ɛ}_{0} {ɛ}_{s} {ϕ}_{f}}{qN}} ,$$
where φ_{f} is a reference Fermi level defining as
$${ϕ}_{f} = \frac{kT}{q} ln ( \frac{N}{{n}_{i}} ) ,$$
N is the free electrons concentrations in the channel N-type region, ε₀ is the free space dielectric constant, ε_{S} is the semiconductor dielectric constant, q is the electron charge, nᵢ is the intrinsic carriers concentration T is the temperature and k is Boltzmann constant.
